(19) United States
(12) Patent Application Publication
(10) Pub. No.: US 2008/0073788 A1
(43) Pub. Date: Mar. 27, 2008

(54) SEMICONDUCTOR DEVICE AND METHOD OF FABRICATING THE SAME

(76) Inventor: Dong-Ki Jeon, Seoul (KR)

Correspondence Address: SHERR & NOURSE, PLLC, 620 HERNDON PARKWAY, SUITE 200, HERNDON, VA, 20170, US

(21) Appl. No.: 11/847,000

(22) Filed: Aug. 29, 2007

(30) Foreign Application Priority Data
Aug. 31, 2006 (KR) 10-2006-0083921

(51) Int. Cl. H01L 23/48; H01L 21/44

(52) U.S. Cl. 257/751; 438/653; 257/E23.01; 257/E21.476

(57) ABSTRACT

A semiconductor device includes a substrate in which a conductive layer is formed; anti-reflective coating layers formed over the conductive layer; and an anti-diffusion layer interposed between the anti-coating layers and the conductive layers.

The present application claims priority under 35 U.S.C. 119 to Korean Patent Application No. 10-2006-0083921 (filed on Aug. 31, 2006), which is hereby incorporated by reference in its entirety.

### BACKGROUND

Electrical lines of semiconductor devices may be formed by depositing an Al—Cu layer having relatively low electrical resistance on and/or over a substrate using a sputtering method and forming patterns using a photolithography process.

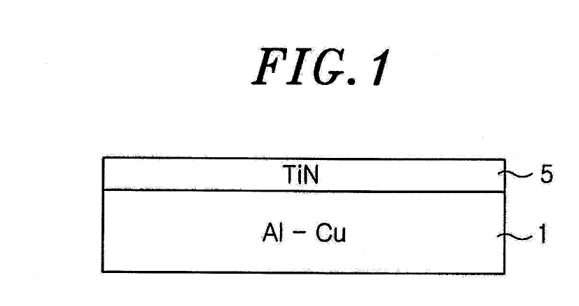

As illustrated in example FIG. 1, a semiconductor device may have an Al—Cu layer 1 with a relatively high reflectivity (e.g. 200% or higher). A relatively high reflectivity may produce a phenomenon whereby ultraviolet (UV) light undergoes diffused reflection from the surface of Al—Cu layer 1, when a photolithography process is carried out on Al—Cu layer 1. In order to prevent or otherwise reduce the occurrence of this phenomenon, titanium nitride (TiN) layer 5 having a specific thickness may be formed on and/or over Al—Cu layer 1. TiN layer 5 may serve as an anti-reflective coating (ARC) layer, which may lower the reflectivity of Al—Cu layer 1.

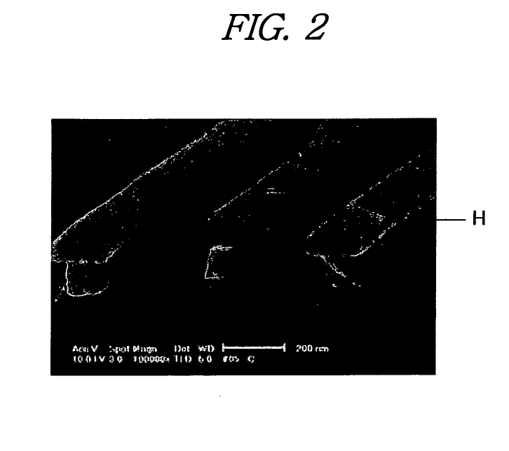

While using TiN layer 5 as an ARC layer may prevent or otherwise reduces the occurrence of diffused reflection of UV light from the surface of Al—Cu layer 1, its use may also produces some undesirable effects. As illustrated in example FIG. 2, providing an ARC layer composed of titanium nitride may result in the formation of hillocks H on the surface of the metal pattern after etching. Such hillocks H may be formed due to stresses acting between Al—Cu layer 1 and TiN layer 5. The formation of hillocks H at the surface of Al—Cu layer 1 may be undesirable since they lower electromigration (EM), reduce the thickness of Al—Cu layer 1, and reduce the length of metal patterns on the semiconductor device. Consequently, the growth of hillocks H may have an effect of reducing the overall reliability of the semiconductor device.

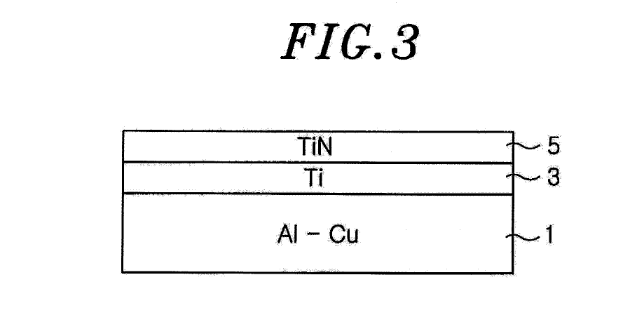

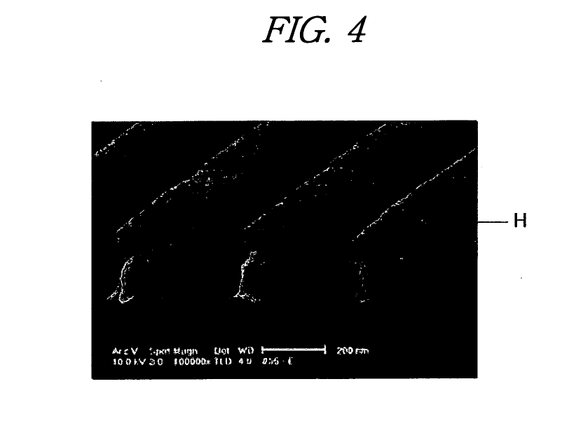

As illustrated in example FIG. 3, one method of reducing stress at the interface between Al—Cu layer 1 and TiN layer 5 is the formation of titanium (Ti) layer 3 at the interface. As illustrated in example FIG. 4, this method, however, causes diffusion between Ti layer and Al—Cu layer 1. Such diffusion produces titanium aluminide (TiAl₃) which reduces the volume of Al—Cu layer 1 at localized areas, and in turn, may cause the formation of hillocks H on the surface of Al—Cu layer 1.

### SUMMARY

Embodiments relate to a semiconductor device including a conductive layer formed on and/or over a substrate; anti-reflective coating layers formed over the conductive layer; and an anti-diffusion layer interposed between the anti-coating layers and the conductive layers.

Embodiments relate to a method of fabricating a semiconductor including at least one of the following steps: forming a conductive layer on and/or over a semiconductor substrate; forming an anti-diffusion layer on and/or over the conductive layer; and forming anti-reflective coating layers on and/or over the anti-diffusion layer. Embodiments may improve the reliability of semiconductor devices by preventing the formation of hillocks in such a manner that the anti-diffusion layers do not react with the conductive layer.

### DRAWINGS

Example FIGS. 1 to 4 illustrate a method of forming a semiconductor device.

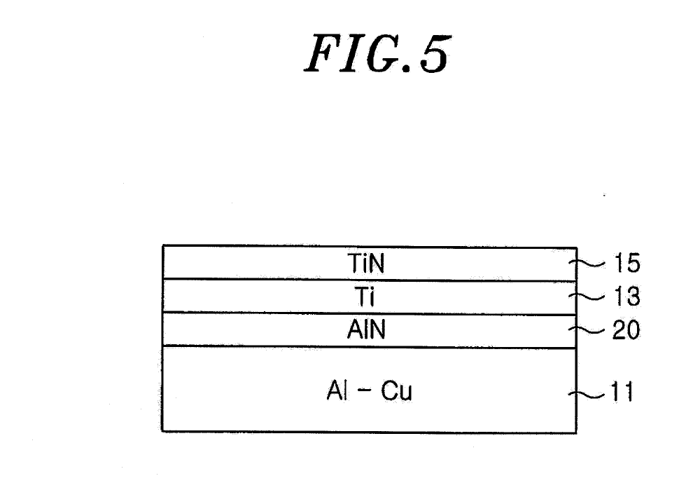

Example FIGS. 5 to 9 illustrate a method of forming a semiconductor device, in accordance with embodiments.

### DESCRIPTION

As illustrated in example FIG. 5, a semiconductor device in accordance with embodiments includes conductive layer 11 formed on and/or over a semiconductor substrate. In embodiments, conductive layer 11 may include a metal pattern such as Al—Cu that may be formed using a photolithography process. Separate anti-reflective coating (ARC) layers 13 and 15 may be formed on and/or over conductive layer 11 in order to reduce the high reflectivity of UV light on the surface of conductive layer 11. Anti-diffusion layer 20 may be formed between conductive layer 11 and ARC layers 13 and 15 to prevent diffusion between conductive layer 11 and ARC layers 13 and 15.

In accordance with embodiments, ARC layers 13 and 15 may have a stacked structural arrangement that includes lower or first ARC layer 13 formed directly on and/or over anti-diffusion layer 20 and upper or second ARC layer 15 formed directly on and/or over first ARC layer 13. In embodiments, first ARC layer 13 may be composed of titanium (Ti) while second ARC layer 15 may be composed of titanium nitride (TiN). This stacked Ti/TiN ARC arrangement yields advantageous qualities to the semiconductor device. For instance, forming TiN layer 15 directly on and/or over Al—Cu layer 11 may result in undesirable hillock formation on the surface of Al—Cu layer 11 due to stress differences between TiN layer 15 and Al—Cu layer 11. However, interposing Ti layer 13 between TiN layer 15 and Al—Cu layer 11 may prevent formation of such hillocks, and thus, may increase the reliability of the semiconductor device.

In accordance with embodiments, anti-diffusion layer 20 is interposed between Ti layer 13 and Al—Cu layer 11. Anti-diffusion layer 20 may be formed using a variety of materials. In order to facilitate the manufacturing process, however, anti-diffusion layer 20 may be composed of aluminum nitride (AlN) formed by nitrifying the surface of Al—Cu layer 11 to form a layer of aluminum nitride having a thickness of between approximately 10 angstrom to approximately 20 angstrom.

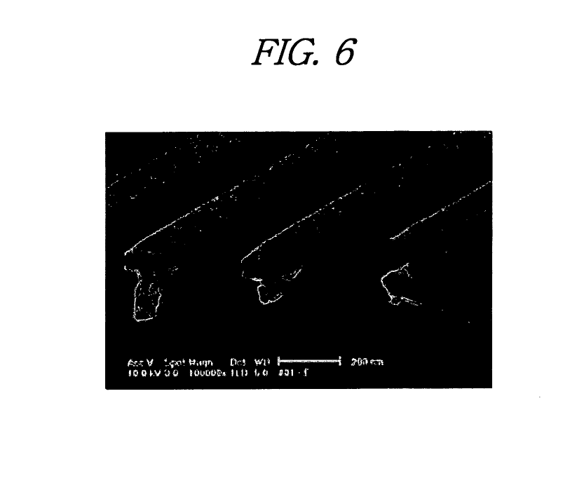

As illustrated in example FIG. 6, obtaining the stated threshold thickness range for anti-diffusion layer 20 in accordance with embodiments may be important in preventing undesirable hillock formation at the Al—Cu surface. For instance, during the nitrifying process hillocks appear due to the formation of titanium aluminide (TiAl₃). The formation of titanium aluminide during the nitrifying process occurs due to the relative disparity in thickness between conductive layer 11 and anti-diffusion layer 20. For example, anti-diffusion layer 20 having a thickness of greater than approximately 20 angstrom will result in Al—Cu layer 11 having a decreased thickness, which narrows the migration paths and results in the formation of titanium aluminide. On the other hand, anti-diffusion layer 20 having a thickness of less than approximately 10 angstrom may result in Al—Cu layer 11 having an increased thickness, which makes it difficult to form additional anti-diffusion layers. This also results in the formation of titanium aluminide.

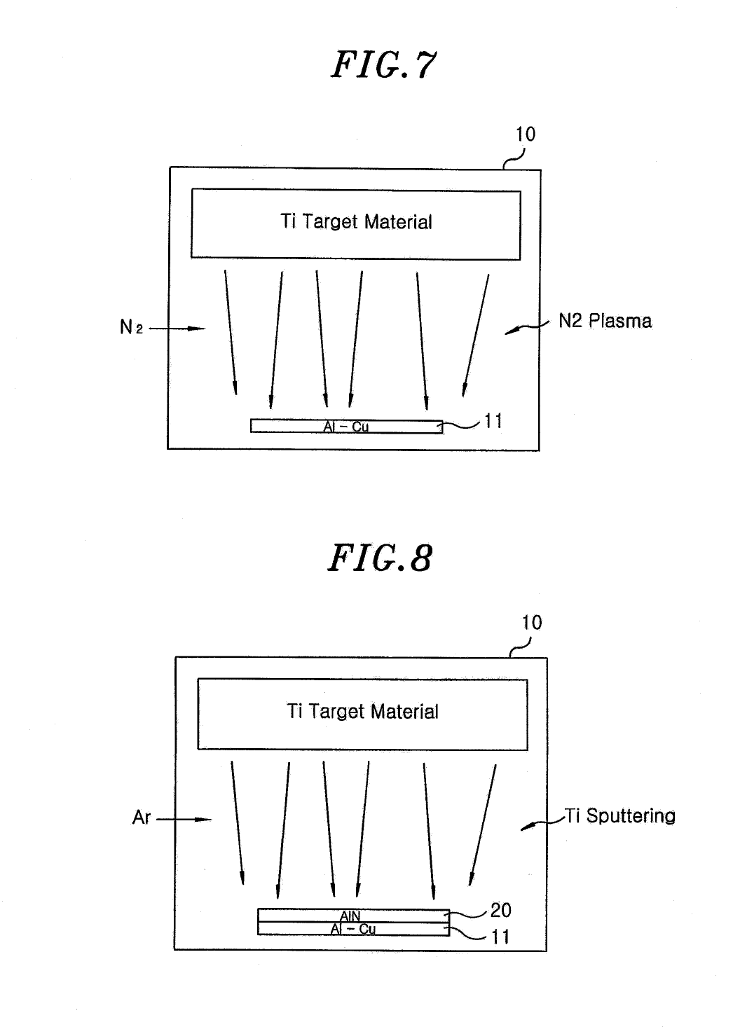

As illustrated in example FIGS. 7-9, a method of fabricating a semiconductor device includes steps of forming conductive layer 11 on and/or over a semiconductor substrate (not shown), forming anti-diffusion layer 20 on and/or over conductive layer, and forming ARC layers 13 and 15 on and/or over anti-diffusion layer 20.

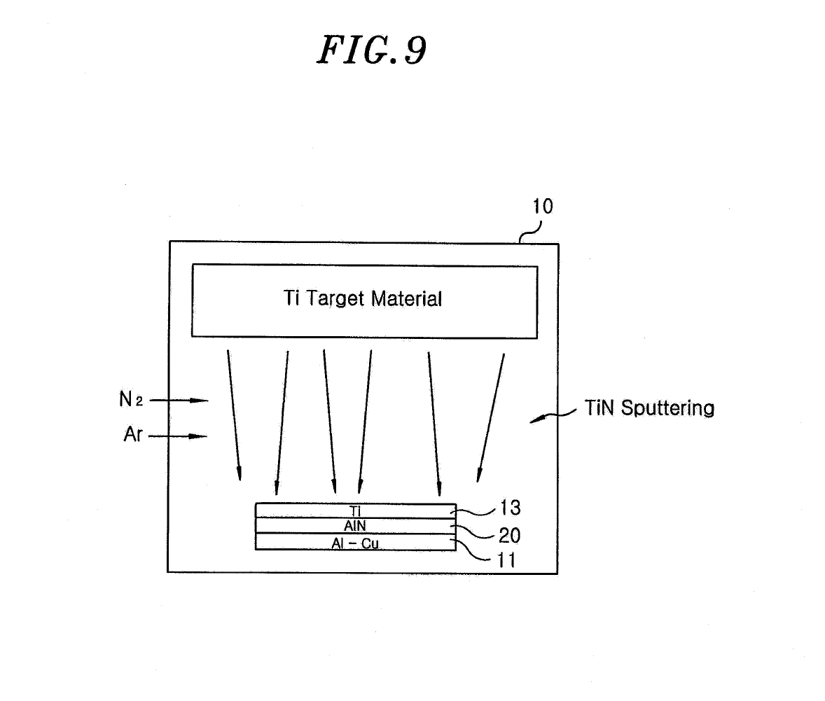

In accordance with embodiments illustrated in example FIG. 7, a semiconductor device on which Al—Cu layer 11 is deposited enters chamber 10. The surface of Al—Cu layer 11 is then nitrified by nitrogen (N₂) plasma within chamber 10 to form aluminum nitride layer 20 having a thickness of between approximately 10 angstrom to approximately 20 angstrom. As illustrated in example FIGS. 8 and 9, titanium layer 13 and titanium nitride layer 15 are formed over aluminum nitride layer 20 by a sputtering process.

In accordance with embodiments, an anti-diffusion layer having a thickness of between approximately 10 angstrom to approximately 20 angstrom is formed on the conductive layer to prevent formation of hillocks on the surface of the conductive layer. The prevention of such hillocks results in enhanced electromigration and reliability of semiconductor devices.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus comprising:
a semiconductor substrate;
a conductive layer formed over the semiconductor substrate;
at least one anti-reflective coating layer formed over the conductive layer; and
an anti-diffusion layer formed between the conductive layer and said at least one anti-reflective coating layer, wherein the anti-diffusion layer is configured to prevent diffusion between the conductive layer and said at least one anti-reflective coating layer.

2. The apparatus of claim 1, wherein the anti-diffusion layer comprises an aluminum nitride layer.

3. The apparatus of claim 2, wherein the anti-diffusion layer has a thickness of between approximately 10 angstroms and approximately 20 angstroms.

4. The apparatus of claim 1, wherein the anti-reflective coating layers comprises stacked layers of titanium and titanium nitride.

5. A method comprising:
forming a conductive layer over a semiconductor substrate;
forming an anti-diffusion layer over the conductive layer; and
forming at least one anti-reflective coating layer over the anti-diffusion layer.

6. The method of claim 5, wherein the anti-diffusion layer is formed by nitrifying the conductive layer.

7. The method of claim 6, wherein the conductive layer comprises aluminum.

8. The method of claim 7, wherein the anti-diffusion layer comprises aluminum nitride.

9. The method of claim 8, wherein said at least one anti-reflective coating layer comprises titanium and titanium nitride.

10. The method of claim 9, wherein said at least one anti-reflective coating layer is formed by a sputtering method.

11. An apparatus comprising:
a semiconductor substrate;
a conductive layer formed over the semiconductor substrate;
an anti-diffusion layer formed over the conductive layer, the anti-diffusion layer having a thickness of between approximately 10 angstrom and approximately 20 angstrom;
a first anti-reflective coating layer formed over the anti-diffusion layer; and
a second anti-reflective coating layer formed over the lower anti-reflective coating layer, wherein the second anti-reflective coating layer is composed of a different material from the first anti-reflective coating layer.

12. The semiconductor device of claim 11, wherein the first anti-reflective coating layer comprises titanium.

13. The semiconductor device of claim 12, wherein the second anti-reflective coating layer comprises titanium nitride.
